(19) United States
(12) Patent Application Publication
(10) Pub. No.: US 2026/0255582 A1
(43) Pub. Date: Aug. 27, 2026

(54) SEMICONDUCTOR MEMORY DEVICE AND MANUFACTURING METHOD THEREOF

(71) Applicant: Fujian Jinhua Integrated Circuit Co., Ltd., Fujian (CN)

(72) Inventor: Yukihiro NAGAI, Fujian (CN)

(73) Assignee: Fujian Jinhua Integrated Circuit Co., Ltd., Fujian (CN)

(21) Appl. No.: 19/346,377

(22) Filed: Sep. 30, 2025

(30) Foreign Application Priority Data
Feb. 26, 2025 (CN) 202510220740.4

(51) Int. Cl. H10B 12/00; H10D 1/68

(52) U.S. Cl. CPC H10B 12/482; H10B 12/03; H10B 12/488; H10D 1/714

(57) ABSTRACT

Embodiments of present invention provide a semiconductor memory device and a manufacturing method thereof. The device includes: a substrate, a plurality of stacked structures isolated from one another in a vertical direction and disposed on the substrate, the stacked structure including a semiconductor layer, and the semiconductor layer including a first doped region, a channel region, and a second doped region. The device further includes a bit line extending along a horizontal direction and being connected to the first doped region, a capacitor structure including bottom electrodes and a top electrode, the bottom electrodes being connected to the second doped region; and a support layer disposed between adjacent bottom electrodes and being in direct contact with sidewalls, upper surfaces, and lower surfaces of the bottom electrodes.

### CROSS-REFERENCE TO RELATED APPLICATION

This application claims priority to Chinese Patent Application No. 202510220740.4, filed on February 26, 2025 and entitled “SEMICONDUCTOR MEMORY DEVICE AND MANUFACTURING METHOD THEREOF”, which is hereby incorporated by reference in its entirety.

### BACKGROUND

### Technical Field

The present application relates to the field of semiconductor technology, and more particularly, to a semiconductor memory device and a manufacturing method thereof.

### Description of Related Art

With the development of semiconductor technology, semiconductor memory devices are widely used in various electronic devices. A semiconductor memory device includes a WL (word line), a BL (bit line), a transistor, and a capacitor structure. A gate of a transistor is connected to a word line, a drain of the transistor is connected to a bit line, and a source of the transistor is connected to a capacitor structure. The transistor is controlled to switch on or switch off through the word line, while data is read from and written into the capacitor structure through the bit line.

With the continuous improvement of the integration level of semiconductor memory devices, the semiconductor memory devices are developing towards a three-dimensional structure with capacitor structure(s) disposed horizontally. However, the capacitor structure is prone to bending, which affects the performance of the semiconductor memory device.

### SUMMARY

Embodiments of the present application provide a semiconductor memory devices and a manufacturing method thereof, to reduce the bending of a capacitor structure and improve the performance of the semiconductor memory device.

In a first aspect, an embodiment of the present application provides a semiconductor memory device including: a substrate; a plurality of stacked structures isolated from one another in a vertical direction and disposed on the substrate. The stacked structure includes a semiconductor layer, and the semiconductor layer includes a first doped region, a channel region, and a second doped region. The semiconductor memory device further includes: a bit line extending along a horizontal direction and being connected to the first doped region; a capacitor structure including a bottom electrode and a top electrode arranged in a stacked configuration, the bottom electrode being connected to the second doped region; and a support layer disposed around the bottom electrode and being in direct contact with a sidewall, an upper surface, and a lower surface of the bottom electrode.

In some embodiments, the bottom electrode includes a first sidewall and a second sidewall that are oppositely disposed, the first sidewall is in direct contact with the support layer, and the second sidewall is in direct contact with the second doped region.

In some embodiments, both an orthographic projection of the top electrode and an orthographic projection of the bottom electrode onto the support layer are located within a contour of a corresponding surface of the support layer.

In some embodiments, a word line is further included. The word line extends along the vertical direction and is adjacent to the channel region.

In some embodiments, an insulating layer and a dielectric layer are further included. The insulating layer is disposed between adjacent semiconductor layers. The dielectric layer is disposed between the bottom electrode and the top electrode, as well as between the support layer and the top electrode, and the dielectric layer covers a portion of a surface of the bottom electrode.

The semiconductor memory device in the embodiments of the present application includes a substrate, a plurality of stacked structures, a bit line, a capacitor structure, and a support layer. The plurality of stacked structures are isolated from one another in the vertical direction and disposed on the substrate. The stacked structure includes a semiconductor layer, and the semiconductor layer includes a first doped region, a channel region, and a second doped region. The bit line extends along a horizontal direction and is connected to the first doped region. The capacitor structure includes a bottom electrode and a top electrode arranged in a stacked configuration. The bottom electrode is connected to the second doped region. The support layer is disposed around the bottom electrode and in direct contact with a sidewall, an upper surface, and a lower surface of the bottom electrode. By directly contacting the bottom electrode and supporting an end of the bottom electrode away from the semiconductor layer, the support layer helps prevent bending of the bottom electrode and bridging between bottom electrodes, thus ensuring the performance of the semiconductor memory device.

In a second aspect, an embodiment of the present application provides a semiconductor memory device including: a substrate; a plurality of stacked structures isolated from one another in a vertical direction and disposed on the substrate. The stacked structure includes a semiconductor layer, and the semiconductor layer includes a first doped region, a channel region, and a second doped region. The semiconductor memory device further includes: a bit line extending along a horizontal direction and being connected to the first doped region; a capacitor structure including a bottom electrode and a top electrode arranged in a stacked configuration, the bottom electrode being connected to the second doped region; an insulating layer disposed between adjacent capacitor structures; a support layer disposed between insulating layers and being in direct contact with sidewalls, upper surfaces, and lower surfaces of the insulating layers.

In some embodiments, the bottom electrode includes a first sidewall and a second sidewall that are oppositely disposed, the first sidewall is in direct contact with the support layer, and the second sidewall is in direct contact with the second doped region.

In some embodiments, both an orthographic projection of the top electrode and an orthographic projection of the bottom electrode onto the support layer are located within a contour of a corresponding surface of the support layer.

In some embodiments, a word line is further included. The word line extends along the vertical direction and is adjacent to the channel region.

In some embodiments, the bit line and the support layer are respectively disposed on opposite sides of the semiconductor layer.

In some embodiments, the insulating layer is further disposed between adjacent semiconductor layers. The semiconductor memory device further includes a dielectric layer, and the dielectric layer is disposed between the bottom electrode and the top electrode. The bottom electrode covers a portion of a surface of the insulating layer.

The semiconductor memory device in the embodiments of the present application includes a substrate, a plurality of stacked structures, a bit line, a capacitor structure, an insulating layer, and a support layer. The plurality of stacked structures are isolated from one another in the vertical direction and disposed on the substrate. The stacked structure includes a semiconductor layer, and the semiconductor layer includes a first doped region, a channel region, and a second doped region. The bit line extends along a horizontal direction and is connected to the first doped region. The capacitor structure includes a bottom electrode and a top electrode arranged in a stacked configuration. The bottom electrode is connected to the second doped region. The insulating layer is disposed between adjacent capacitor structures, and the support layer is disposed between insulating layers and in direct contact with sidewalls, upper surfaces, and lower surfaces of the insulating layers. In this way, an end of the insulating layer extends into the support layer, which provides support for the insulating layer, thus maintaining the stability of the insulating layer, and preventing the insulating layer from bending. Consequently, it avoids the bridging of capacitor structures formed on the insulating layers subsequently due to their bending, thereby ensuring the performance of the semiconductor memory device.

In a third aspect, an embodiment of the present application provides a manufacturing method of a semiconductor memory device, including: providing a substrate; and forming a plurality of stacked structures, a bit line, a capacitor structure, and a support layer. The plurality of stacked structures are isolated from one another in a vertical direction and disposed on the substrate. The stacked structure includes a semiconductor layer, and the semiconductor layer includes a first doped region, a channel region, and a second doped region. The bit line extends along a horizontal direction and is connected to the first doped region. The capacitor structure includes a bottom electrode and a top electrode arranged in a stacked configuration. The bottom electrode is connected to the second doped region. The support layer is in contact with a sidewall of the capacitor structure.

In some embodiments, the support layer is disposed around the bottom electrode and in direct contact with a sidewall, an upper surface, and a lower surface of the bottom electrode.

In some possible embodiments, the method further includes forming an insulating layer. The insulating layer is disposed between adjacent capacitor structures, and the support layer is disposed between insulating layers and in direct contact with sidewalls, upper surfaces, and lower surfaces of the insulating layers.

In some embodiments, the method further includes forming a dielectric layer, where the dielectric layer is disposed between the bottom electrode and the top electrode, and the bottom electrode covers a portion of a surface of the insulating layer.

In some embodiments, the insulating layer is further disposed between adjacent semiconductor layers.

In some possible embodiments, the dielectric layer is disposed between the bottom electrode and the top electrode, as well as between the support layer and the top electrode, and the dielectric layer covers a portion of a surface of the bottom electrode.

The manufacturing method of a semiconductor memory device provided in the embodiments of the present application includes: providing a substrate; and forming a plurality of stacked structures, a bit line, a capacitor structure, and a support layer. The plurality of stacked structures are isolated from one another in a vertical direction and disposed on the substrate. The stacked structure includes a semiconductor layer, and the semiconductor layer includes a first doped region, a channel region, and a second doped region. The bit line extends along a horizontal direction and is connected to the first doped region. The capacitor structure includes a bottom electrode and a top electrode arranged in a stacked configuration. The bottom electrode is connected to the second doped region. The support layer is in contact with a sidewall of the capacitor structure. The support layer can provide support during the formation of the capacitor structure, thereby avoiding bending of the capacitor structure and enhancing the performance of the semiconductor memory device formed.

### BRIEF DESCRIPTION OF THE DRAWINGS

The accompanying drawings are incorporated into the specification and form a part of the specification, illustrating embodiments in accordance with the present application and used together with the specification to explain the principles of the present application.

FIG. 1 is a schematic diagram of a semiconductor memory device of the present application.

FIG. 2 is a schematic diagram in which an isolation layer of FIG. 1 is hidden.

FIG. 3 is a schematic diagram of the present application after the formation of a support layer.

FIG. 4 is a schematic diagram of the present application after the removal of a portion of an insulating layer.

FIG. 5 is a schematic diagram in which an isolation layer of FIG. 4 is shown.

FIG. 6 is a schematic diagram of the present application after the formation of a top electrode.

FIG. 7 is a top view of a semiconductor memory device of the present application.

FIG. 8 is a cross-sectional view of a semiconductor memory device of the present application.

FIG. 9 is another schematic diagram of the present application after the formation of a bottom electrode.

FIG. 10 is another schematic diagram of the present application after the formation of a top electrode.

FIG. 11 is another cross-sectional view of a semiconductor memory device of the present application.

### DESCRIPTION OF THE EMBODIMENTS

Exemplary embodiments will be described in detail, with examples shown in the accompanying drawings. When referring to the accompanying drawings, unless otherwise indicated, the same number in different drawings represent the same or similar element. The implementations described in the following exemplary embodiments do not represent all implementations consistent with the present application. On the contrary, they are only examples of a devices and a method consistent with some aspects of the present application as described in the claims.

The semiconductor memory device of the present application can reduce the bending of a bottom electrode by providing a support layer to directly support the bottom electrode, or to directly support an insulating layer used for the deposition of the bottom electrode, thereby avoiding the bridging of bottom electrodes and enhancing the performance of the semiconductor memory device.

Below is a detailed explanation of the technical solution of the present application and how the technical solution of the present application solves the above technical problem through specific embodiments. The following specific embodiments may be combined with each other, and the same or similar concepts or processes may not be repeated in some embodiments. Hereinafter, the embodiments of the present application will be described in combination with the accompanying drawings.

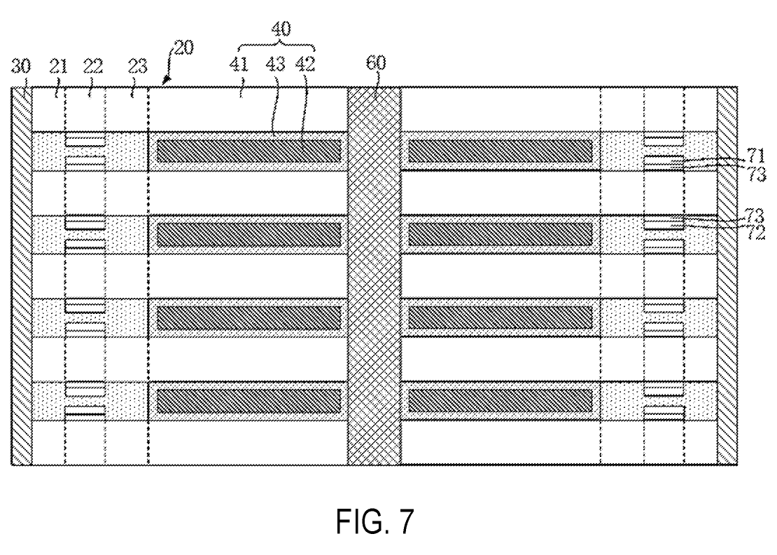

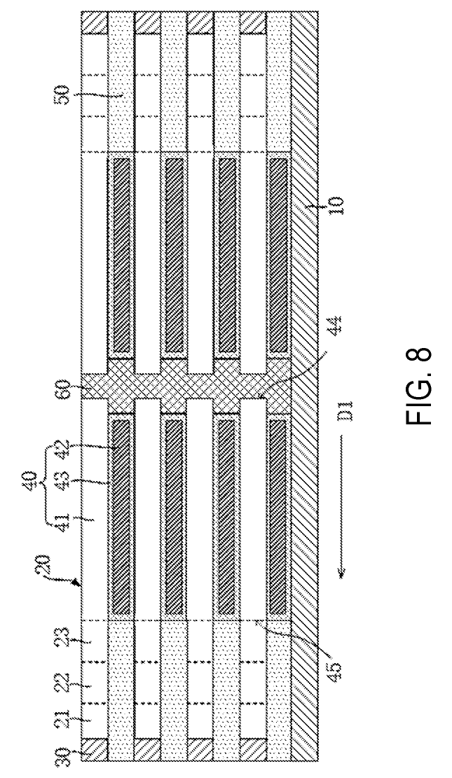

Referring to FIG. 6, FIG. 7, and FIG. 8, an embodiment of the present application provides a semiconductor memory device, such as, a dynamic random access memory (Dynamic Random Access Memory, DRAM). The semiconductor memory device includes a substrate 10, a plurality of stacked structures, a bit line 30, a capacitor structure 40, and a support layer 60. Among them, the substrate 10 provides support for the structures thereon, such as, for the stacked structures, the support layer 60, and etc. The substrate 10 is, for example, a silicon substrate, a silicon-containing (such as, silicon germanium) substrate, or a silicon on insulator (such as, Silicon On Insulator, SOI) substrate.

The plurality of stacked structures are isolated from one another in a vertical direction and disposed on the substrate 10. The plurality of stacked structures include semiconductor layers 20. The semiconductor layer 20 includes a first doped region 21, a channel region 22, and a second doped region 23. Among them, the plurality of stacked structures are arranged at intervals on the substrate 10, and the arrangement direction of the plurality of stacked structures is D3 as shown in FIG. 6. The isolation layer 90 is formed (filled) at least between adjacent stacked structures, which is applied to achieve mutual isolation among the stacked structures.

Exemplarily, the isolation layer 90 is disposed on the substrate 10 (referring to FIG. 6 to FIG. 9) and extends along the vertical direction. The isolation layer 90 is applied to ensure that there is no mutual conductivity between the stacked structures in the vertical direction. Among them, a top surface of the isolation layer 90 may be either higher than or flush with top surfaces of the stacked structures. A top surface refers to a surface away from the substrate 10. The vertical direction refers to a direction perpendicular to the top surface of the substrate 10, that is, D2 as shown in FIG. 6. The isolation layer 90 is made of a material including an insulating material, such as, silicon oxide, silicon nitride, carbon nitride silicon, or the like.

Each stacked structure includes at least one semiconductor layer 20. These semiconductor layers 20 are arranged at intervals in the vertical direction. The semiconductor layer(s) 20 in each stacked structure may be in contact with the substrate 10 or spaced apart from the substrate 10 (as shown in FIG. 8). The semiconductor layer 20 is made of a material including a semiconductor material, such as, monocrystalline silicon, polycrystalline silicon, amorphous silicon, or the like.

Each semiconductor layer 20 includes a first doped region 21, a channel region 22, and a second doped region 23 that are sequentially arranged. That is, two sides of the channel region 22 are respectively connected to the first doped region 21 and the second doped region 23. Among them, the first doped region 21, the channel region 22, and the second doped region 23 are adjacent in sequence and parallel to the top surface of the substrate 10. The arrangement direction of the first doped region 21, the channel region 22, and the second doped region 23 is a direction D1 as shown in FIG. 6 and FIG. 8, which may also be considered as an extension direction of the semiconductor layer 20.

A surface of the first doped region 21 and a surface of the channel region 22 that face each other may be overlapping, e.g., completely coincide. A surface of the second doped region 23 and a surface of the channel region 22 that face each other may be overlapping, e.g., completely coincide. Both the first doped region 21 and the second doped region 23 may be heavily doped regions, with doping achieved, for example, through ion implantation. The first doped region 21 may be used as a drain (Drain), which is connected to the bit line 30, and the second doped region 23 may be used as a source (Source), which is connected to the capacitor structure 40.

To achieve mutual isolation between adjacent semiconductor layers 20 within the same stacked structure, the stacked structure further includes an insulating layer 50, which is disposed between adjacent semiconductor layers 20. The insulating layer 50 is formed (filled) at least between adjacent semiconductor layers 20, and is in complete contact with surfaces of two adjacent semiconductor layers 20 that face each other, thus ensuring effective isolation among the semiconductor layers 20. The insulating layer 50 is made of a material including, for example, silicon oxide, silicon nitride, phosphosilicate glass, or the like.

Continuing to refer to FIG. 7 and FIG. 8, the bit line 30 is disposed on the substrate 10 and extends along a horizontal direction. The horizontal direction is parallel to the top surface of substrate 10. The bit line 30 is electrically connected to the first doped region 21. That is, there exists electrical conductivity between the bit line 30 and the first doped region 21. In some embodiments, a height of the bit line 30 matches that of the semiconductor layer 20. A top surface of the bit line 30 is higher than a bottom surface of the semiconductor layer 20, where the bit line 30 is connected to the semiconductor layer 20; and the top surface of the bit line 30 is lower than or flush with a top surface of its connected semiconductor layer 20. Alternatively, a bottom surface of the bit line 30 is higher than or flush with a bottom surface of its connected semiconductor layers 20, and is lower than a top surface of its connected semiconductor layer 20. Specifically, a top surface of the bit line 30 is flush with a top surface of its connected semiconductor layer 20, and a bottom surface of the bit line 30 is flush with a bottom surface of its connected semiconductor layer 20, thus facilitating the fabrication of the bit line 30 and improving the transmission performance between the bit line 30 and the corresponding semiconductor layer 20.

In some possible examples, an extension direction of the bit line 30 is parallel to the arrangement direction of the plurality of stacked structures, so that the bit line 30 may connect to a plurality of semiconductor layers 20, and the plurality of semiconductor layers 20 are located in different stacked structures, to simplify the structure of the semiconductor memory device and facilitate the improvement of storage density. Among them, the extension direction of the bit line 30 is a direction D3 as shown in FIG. 6. The bit line 30 may have a single-layer structure or a multiple-layer structure. Exemplarily, the bit line 30 includes a first conductor layer. The first conductor layer is made of a material including a metal material, such as, a low-resistance metal material (including tungsten, aluminum, copper, or the like). The specific structure of the bit line 30 in the embodiments of the present application is not limited. There may be multiple bit lines 30, which are arranged at intervals in the vertical direction to avoid connections between adjacent bit lines 30. The number of the bit lines 30 may be consistent with the number of semiconductor layers 20 in the stacked structure, enabling each semiconductor layer 20 within each stacked structure to be individually lead out through the corresponding bit line 30.

Continuing to refer to FIG. 6 to FIG. 8, the capacitor structure 40 may store data. It includes a bottom electrode 41 and a top electrode 42 arranged in a stacked configuration, and the bottom electrode 41 and the top electrode 42 are spaced apart from each other. Among them, the bottom electrode 41 is connected to the second doped region 23. Exemplarily, the bottom electrode 41 is disposed on a surface of the second doped region 23 away from the channel region 22. That is, the first doped region 21, the channel region 22, the second doped region 23, and the bottom electrode 41 are sequentially arranged. Surfaces of the bottom electrode 41 and the second doped region 23 that face each other are in close contact, e.g., completely coincide.

The bottom electrode 41 is made of a material, for example, the same as that of the semiconductor layer 20, so that the bottom electrode 41 and the semiconductor layer 20 form an integrated structure, that is, the bottom electrode 41 may be a portion of the semiconductor layer 20. This facilitates the simultaneous production of the bottom electrode 41 and the semiconductor layer 20. An upper surface and a lower surface of the bottom electrode 41 are oppositely disposed in the vertical direction. An end of the bottom electrode 41 away from the second doped region 23 is located within the support layer 60. The support layer 60 is used to provide support for the capacitor structure 40, thus preventing the capacitor structure 40 from collapsing and ensuring the performance of the semiconductor memory device. Exemplarily, the bottom electrode 41 includes a first side wall 44 and a second side wall 45 that are oppositely disposed, the first side wall 44 being in direct contact with the support layer 60, and the second side wall 45 being in direct contact with the second doped region 23.

The top electrode 42 is disposed between adjacent bottom electrodes 41, and the top electrode 42 is staggered with the semiconductor layers 20 in the vertical direction. The top electrode 42 is disposed on a surface of the insulating layer 50 facing the support layer 60, and further surrounds an outer circumference surface of the bottom electrode 41. That is, the top electrode 42 is sleeved on the bottom electrode 41 and spaced apart from the bottom electrode 41. The top electrode 42 may have an integrated structure. That is, a plurality of bottom electrodes 41 share one top electrode 42. The top electrode 42 is formed, for example, through a deposition process to facilitate the production of the top electrode 42. The top electrode 42 is made of a material including a low-resistance metal material (such as, titanium nitride, aluminum, titanium, copper, tungsten, or the like), or a semiconductor material (such as, silicon germanium, or the like), or a combination of the above materials.

Continuing to refer to FIG. 6 to FIG. 8, the capacitor structure 40 further includes a dielectric layer 43. The dielectric layer 43 is disposed between the bottom electrode 41 and the top electrode 42, as well as between the support layer 60 and the top electrode 42. The dielectric layer 43 covers a portion of a surface of the bottom electrode 41. For example, the dielectric layer 43 covers a portion of an outer circumference surface of one end of the bottom electrode 41 adjacent to the second doped region 23. An end of the bottom electrode 41 away from the second doped region 23 extends into the support layer 60, and this end remains uncovered by the dielectric layer 43. The dielectric layer 43, for example, covers the top electrode 42, to isolate the top electrode 42 from the bottom electrode 41, as well as to isolate the top electrode 42 from the support layer 60. The dielectric layer 43 is made of a material including, for example, silicon oxide, zirconium oxide, aluminum oxide, or the like.

The support layer 60 may extend along the vertical direction and be in direct contact with a sidewall, an upper surface, and a lower surface of the bottom electrode 41. Among them, the upper surface and the lower surface of the bottom electrode 41 are oppositely disposed in the vertical direction, and the side wall of the bottom electrode 41 is connected to the upper surface and the lower surface of the bottom electrode 41. The support layer 60 is in direct contact with the bottom electrode 41 and supports an end of the bottom electrode 41 away from the semiconductor layer 20, which can avoid bending of the bottom electrode 41 and bridging between bottom electrodes 41, thereby ensuring the performance of the semiconductor memory device. The support layer 60 is made of a material including an insulating material with high hardness, such as, silicon nitride, silicon carbide nitride, or the like. Among them, stacked structures may also be disposed on opposite sides of the support layer 60, that is, the stacked structures may also be arranged along the direction D1 as shown in FIG. 8. In this way, the support layer 60 may provide support for the stacked structures on both sides to improve the storage density of the semiconductor memory device.

In the example where the bottom electrode 41 includes the first side wall 44 and the second side wall 45 that are oppositely disposed, the support layer 60 covers the end of the bottom electrode 41 away from the second doped region 23. Specifically, the support layer 60 covers the first side wall 44 of the bottom electrode 41, as well as a portion of the upper surface of the bottom electrode 41 and a portion of the lower surface of the bottom electrode 41 adjacent to the first side wall 44. As shown in FIG. 8, the support layer 60 is also in direct contact with a surface of the dielectric layer 43 on a side away from the insulating layer 50. It can be understood that the end of the bottom electrode 41, which is away from the second doped region 23, protrudes from an end of the dielectric layer 43 away from the insulating layer 50, so that the support layer 60 covers this end of the bottom electrode 41, thereby providing support.

In some embodiments, both an orthographic projection of the top electrode 42 and an orthographic projection of the bottom electrode 41 onto the support layer 60 are located within the contour of corresponding surfaces of the support layer 60. As shown in FIG. 7 and FIG. 8, the orthographic projection of the bottom electrode 41 onto the support layer 60 is located within the contour of the corresponding surface of the support layer 60, and the orthographic projection of the top electrode 42 onto the support layer 60 is also located within the contour of the corresponding surface of the support layer 60. Therefore, in both the vertical direction and the horizontal direction, the support layer 60 has a larger area, so that the support layer 60 can fully support all bottom electrodes 41 and make complete contact with the first side walls 44 of the bottom electrodes 41. This configuration can enhance the support effect. At the same time, it can also increase the contact area between the support layer 60 and the dielectric layer 43, further improving the support provided by the support layer 60.

Continuing to refer to FIG. 6 to FIG. 8, the semiconductor memory device further includes a word line extending along the vertical direction and being adjacent to the channel region 22. Specifically, the word line extends along a direction away from a top surface of the substrate 10. The word line is adjacent to the channel region 22 and is also used to form a gate, thereby controlling the channel region 22 to switch on or off. The word line may correspond to channel regions 22 of a plurality of semiconductor layers 20 within the same stacked structure, to simultaneously control the switching on or off of the plurality of channel regions 22.

In some embodiments, the word line includes a first word line 71 and a second word line 72. The first word line 71 is adjacent to a first side of the channel region 22, and the second word line 72 is adjacent to a second side of the channel region 22. The second side of the channel region 22 is opposite to the first side of the channel region 22 along an extension direction of the bit line 30. As shown in FIG. 6, the first word line 71 and the second word line 72 are disposed on the first side and the second side of the channel region 22, respectively. Among them, the first word line 71 is adjacent to the first side of the channel region 22 and is opposite to at least a portion of the channel region 22, while the second word line 72 is adjacent to the second side of the channel region 22 and is opposite to at least a portion of the channel region 22. The first side of the channel region 22 and the second side of the channel region 22 are opposite along the extension direction of the bit line 30, so that the channel region 22 can be controlled by two word lines.

It can be understood that in the first word line 71 and the second word line 72, regions facing the channel region 22 and aligned along the extension direction of the bit line 30 form a gate structure. A structure of the first word line 71 and a structure of the second word line 72 may be the same or different. The first word line 71 and the second word line 72 may be of a single-layer or multiple-layer structure, for example, including a second conductor layer. The second conductor layer is made of a material including a semiconductor material (such as, doped polycrystalline silicon, doped amorphous silicon, or the like), or a low-resistance metal material (such as, tungsten, aluminum, copper, or the like), which is not limited in the embodiments of the present application.

In order to achieve the control functions of the first word line 71 and the second word line 72, the semiconductor memory device further includes gate oxide layers 73, which are disposed at least between the first word line 71 and the channel region 22, as well as between the second word line 72 and the channel region 22. For example, the gate oxide layers 73 extend along the vertical direction. That is, a gate oxide layer 73 is provided between the first word line 71 and the insulating layer 50, and a gate oxide layer 73 is provided between the second word line 72 and the insulating layer 50. The gate oxide layer 73 is made of a material including silicon oxide, hafnium oxide, or the like.

The semiconductor memory device in the embodiments of the present application includes a substrate 10, a plurality of stacked structures, a bit line 30, a capacitor structure 40, and a support layer 60. The plurality of stacked structures are isolated from one another in a vertical direction and disposed on the substrate 10. The stacked structure includes a semiconductor layer 20. The semiconductor layer 20 includes a first doped region 21, a channel region 22, and a second doped region 23. The bit line 30 extends along a horizontal direction and is connected to the first doped region 21. The capacitor structure 40 includes a bottom electrode 41 and a top electrode 42 arranged in a stacked configuration. The bottom electrode 41 is connected to the second doped region 23. The support layer 60 is disposed around the bottom electrode 41, and is in direct contact with a sidewall, an upper surface, and a lower surface of the bottom electrode 41. By directly contacting the bottom electrode 41 and supporting an end of the bottom electrode 41 away from the semiconductor layer 20, the support layer 60 helps prevent bending of the bottom electrode 41 and bridging between bottom electrodes 41, thus ensuring the performance of the semiconductor memory device.

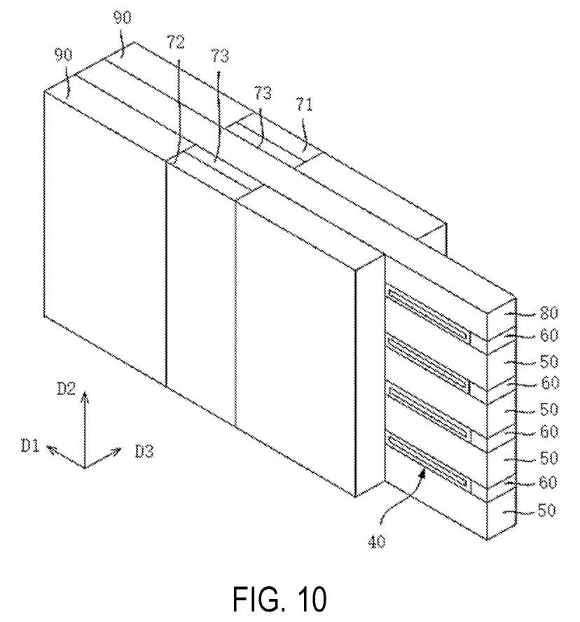

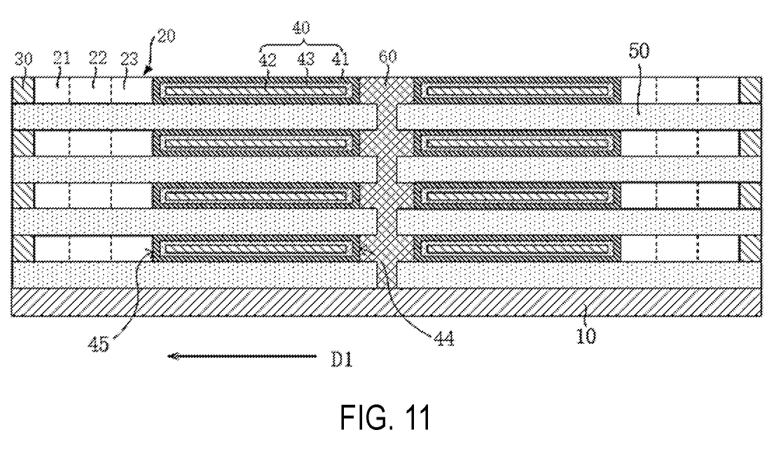

An embodiment of the present application further provides a semiconductor memory device, such as a dynamic random access memory. Referring to FIG. 10 and FIG. 11, the semiconductor memory device includes a substrate 10, a plurality of stacked structures, a bit line 30, a capacitor structure 40, an insulating layer 50, and a support layer 60. Among them, the substrate 10 provides support for structures thereon, such as, for the stacked structures, the support layer 60, and etc. The substrate 10 is, for example, a silicon substrate, a silicon-containing (such as, silicon germanium) substrate, or a silicon on insulator (such as, SOI) substrate.

The plurality of stacked structures are isolated from one another in a vertical direction and disposed on the substrate 10. The plurality of stacked structures include a semiconductor layer 20. The semiconductor layer 20 includes a first doped region 21, a channel region 22, and a second doped region 23. Among them, the plurality of stacked structures are arranged at intervals on the substrate 10, and an arrangement direction of the plurality of stacked structures is D3 as shown in FIG. 10. The isolation layer 90 is formed (filled) at least between adjacent stacked structures, which is applied to achieve mutual isolation among the stacked structures.

Exemplarily, the isolation layer 90 is disposed on the substrate 10 and extends along the vertical direction. The isolation layer 90 is applied to ensure that there is no mutual conductivity between the stacked structures in the vertical direction. Among them, a top surface of the isolation layer 90 may be either higher than or flush with top surfaces of the stacked structures. A top surface refers to a surface away from the substrate 10. The vertical direction refers to a direction perpendicular to the top surface of the substrate 10, that is, D2 as shown in FIG. 10. The isolation layer 90 is made of a material including an insulating material, such as, silicon oxide, silicon nitride, carbon nitride silicon, or the like.

Each stacked structure includes at least one semiconductor layer 20. These semiconductor layers 20 are arranged at intervals in the vertical direction. The semiconductor layer(s) 20 in each stacked structure may be in contact with the substrate 10 or spaced apart from the substrate 10. The semiconductor layer 20 is made of a material including a semiconductor material, such as, monocrystalline silicon, polycrystalline silicon, amorphous silicon, or the like.

Each semiconductor layer 20 includes a first doped region 21, a channel region 22, and a second doped region 23 that are sequentially arranged. That is, two sides of the channel region 22 are respectively connected to the first doped region 21 and the second doped region 23. Among them, the first doped region 21, the channel region 22, and the second doped region 23 are adjacent in sequence and parallel to the top surface of the substrate 10. The arrangement direction of the first doped region 21, the channel region 22, and the second doped region 23 is a direction D1 as shown in FIG. 10 and FIG. 11, which may also be considered as an extension direction of the semiconductor layer 20.

A surface of the first doped region 21 and a surface of the channel region 22 that face each other may be overlapping, e.g., completely coincide. A surface of the second doped region 23 and a surface of the channel region 22 that face each other may be overlapping, e.g., completely coincide. Both the first doped region 21 and the second doped region 23 may be heavily doped regions, with doping achieved, for example, through ion implantation. The first doped region 21 may be used as a drain, which is connected to the bit line 30, and the second doped region 23 may be used as a source, which is connected to the capacitor structure 40.

The bit line 30 is disposed on the substrate 10 and extends along a horizontal direction. The horizontal direction is parallel to the top surface of substrate 10. The bit line 30 is electrically connected to the first doped region 21. That is, there exists electrical conductivity between the bit line 30 and the first doped region 21. In some embodiments, a height of the bit line 30 matches that of the semiconductor layer 20. A top surface of the bit line 30 is higher than a bottom surface of the semiconductor layer 20 to which the bit line 30 is connected and is lower than or flush with a top surface of its connected semiconductor layer 20. Alternatively, a bottom surface of the bit line 30 is higher than or flush with a bottom surface of its connected semiconductor layer 20, and is lower than a top surface of its connected semiconductor layer 20. Specifically, a top surface of the bit line 30 is flush with a top surface of its connected semiconductor layer 20, and a bottom surface of the bit line 30 is flush with a bottom surface of its connected semiconductor layer 20, so that the bit line 30 and the semiconductor layer 20 are disposed on the same layer, thus facilitating the fabrication of the bit line 30 and improving the transmission performance between the bit line 30 and the corresponding semiconductor layer 20.

In some possible examples, an extension direction of the bit line 30 is parallel to the arrangement direction of the plurality of stacked structures, so that the bit line 30 may connect to a plurality of semiconductor layers 20, and the plurality of semiconductor layers 20 are located in different stacked structures, to simplify the structure of the semiconductor memory device and facilitate the improvement of storage density. Among them, the extension direction of bit line 30 is a direction D3 as shown in FIG. 10. The bit line 30 may have a single-layer structure or a multiple-layer structure. Exemplarily, the bit line 30 includes a first conductor layer. The first conductor layer is made of a material including a metal material, such as, a low-resistance metal material (including tungsten, aluminum, copper, or the like). The specific structure of the bit line 30 in the embodiments of the present application is not limited. There may be multiple bit lines 30, which are arranged at intervals in the vertical direction to avoid connections between adjacent bit lines 30. The number of the bit lines 30 may be consistent with the number of semiconductor layers 20 in the stacked structure, enabling each semiconductor layer 20 within each stacked structure to be individually lead out through the corresponding bit line 30.

Continuing to refer to FIG. 10 and FIG. 11, the capacitor structure 40 may store data. It includes a bottom electrode 41 and a top electrode 42 arranged in a stacked configuration, and the bottom electrode 41 and the top electrode 42 are spaced apart from each other. Among them, the bottom electrode 41 is connected to the second doped region 23. Exemplarily, the bottom electrode 41 is disposed on a surface of the second doped region 23 away from the channel region 22. That is, the first doped region 21, the channel region 22, the second doped region 23, and the bottom electrode 41 are sequentially arranged. Surfaces of the bottom electrode 41 and the second doped region 23 that face each other are in close contact, e.g., completely coincide.

Exemplarily, the bottom electrode 41 includes a first side wall 44 and a second side wall 45 that are oppositely disposed, the first side wall 44 being in direct contact with the support layer 60, and the second side wall 45 being in direct contact with the second doped region 23. A surface of the bottom electrode 41 facing away from the second doped region 23 is in close contact with the support layer 60. The bottom electrode 41 is made of a material including a low-resistance metal material (such as, titanium nitride, aluminum, titanium, copper, tungsten, or the like), or a semiconductor material (such as, silicon germanium, or the like), or a combination of the above materials.

A portion of the top electrode 42 is disposed inside the bottom electrode 41. That is, the bottom electrode 41 surrounds the portion of the top electrode 42. The top electrode 42 is opposite to the bottom electrode 41 and is spaced apart from the bottom electrode 41. The top electrode 42 may have an integrated structure. That is, a plurality of bottom electrodes 41 share one top electrode 42. The top electrode 42 is formed, for example, through a deposition process to facilitate the production of the top electrode 42. The top electrode 42 is made of a material including a low-resistance metal material (such as, titanium nitride, aluminum, titanium, copper, tungsten, or the like), or a semiconductor material (such as, silicon germanium, or the like), or a combination of the above materials.

In some embodiments, both an orthographic projection of the top electrode 42 and an orthographic projection of the bottom electrode 41 onto the support layer 60 are located within the contour of corresponding surfaces of the support layer 60. As shown in FIG. 10 and FIG. 11, the orthographic projection of the bottom electrode 41 onto the support layer 60 is located within the contour of the corresponding surface of the support layer 60, and the orthographic projection of the top electrode 42 onto the support layer 60 is also located within the contour of the corresponding surface of the support layer 60. Therefore, in both the vertical direction and the horizontal direction, the support layer 60 has a larger area, so that the support layer 60 can fully support all bottom electrodes 41 and make complete contact with the first side walls 44 of the bottom electrodes 41. This configuration can enhance the support effect. At the same time, it can also increase the contact area between the support layer 60 and a dielectric layer 43, further improving the support provided by the support layer 60.

The semiconductor memory device further includes a dielectric layer 43. The dielectric layer 43 is disposed between the bottom electrode 41 and the top electrode 42. The dielectric layer 43 is made of a material including, for example, silicon oxide, zirconium oxide, aluminum oxide, or the like. In order to achieve the isolation between capacitor structures 40 in the vertical direction, the insulating layer 50 is disposed between adjacent capacitor structures 40, specifically between adjacent bottom electrodes 41. The insulating layer 50 is made of a material including, for example, silicon oxide, silicon nitride, phosphosilicate glass, or the like.

Among them, the insulating layer 50 is also disposed between adjacent semiconductor layers 20. In this way, the insulating layer 50 is applied to further achieve isolation between adjacent semiconductor layers 20 in the vertical direction. Furthermore, the insulating layer 50 also extends between adjacent bit lines 30 to achieve isolation between adjacent bit lines 30 in the vertical direction. As shown in FIG. 11, the bottom electrode 41 covers a portion of a surface of the insulating layer 50, the semiconductor layer 20 covers a portion of a surface of the insulating layer 50, and the bit line 30 covers a portion of a surface of the insulating layer 50.

In some possible examples, the insulating layer 50 includes a first end and a second end that are oppositely disposed. The first end of the insulating layer 50 may protrude from an end of the bit line 30 away from the first doped region 21 or be flush with the end of the bit line 30 away from the first doped region 21, and the second end of the insulating layer 50 protrudes from an end of the bottom electrode 41 away from the second doped region 23. The first end and the second end of the insulating layer 50 are oppositely disposed along an arrangement direction of the semiconductor layer 20 and the capacitor structure 40.

Continuing to refer to FIG. 10 and FIG. 11, the support layer 60 is disposed between insulating layers 50 and in direct contact with sidewalls, upper surfaces, and lower surfaces of the insulating layers 50. In this way, an end of the insulating layer 50 extends into the support layer 60, and the support layer 60 provides support for the insulating layer 50. This helps maintain the stability of the insulating layer 50 and avoid bending of the insulating layer 50. Consequently, it avoids the bridging of capacitor structures 40 formed on the insulating layers 50 subsequently due to their bending, thereby ensuring the performance of the semiconductor memory device. Among them, the upper surface and the lower surface of the insulating layer 50 are arranged at intervals in the vertical direction, and the sidewall of the insulating layer 50 is a surface on a side of the insulating layer 50 that is away from the bit line 30. The stacked structures may also be disposed on opposite sides of the support layer 60, that is, the stacked structures may also be arranged along a direction D1 as shown in FIG. 10 and FIG. 11. In this way, the support layer 60 may provide support for the stacked structures on both sides to improve the storage density of the semiconductor memory device.

In some embodiments, the bit line 30 and the support layer 60 are respectively disposed on opposite sides of the semiconductor layer 20. The bit line 30 is disposed on a side of the semiconductor layer 20, the capacitor structure 40 is disposed on the other side of the semiconductor layer 20, and the support layer 60 is disposed on a side of the capacitor structure 40 away from the semiconductor layer 20. The support layer 60 is in direct contact with a surface of the bottom electrode 41 away from the second doped region 23, and it is also in direct contact with a portion of the upper surface, a portion of the lower surface, and a sidewall away from the bit line 30 of the insulating layer 50.

Continuing to refer to FIG. 10 and FIG. 11, the semiconductor memory device further includes a word line extending along the vertical direction and being adjacent to the channel region 22. Specifically, the word line extends along a direction away from a top surface of the substrate 10. The word line is adjacent to the channel region 22 and is also used to form a gate, thereby controlling the channel region 22 to switch on or off. The word line may correspond to channel regions 22 of a plurality of semiconductor layers 20 in the same stacked structure, to simultaneously control the switching on or off of the plurality of channel regions 22.

In some embodiments, the word line includes a first word line 71 and a second word line 72. The first word line 71 is adjacent to a first side of the channel region 22, and the second word line 72 is adjacent to a second side of the channel region 22. The second side of the channel region 22 is opposite to the first side of the channel region 22 along an extension direction of the bit line 30. As shown in FIG. 10, the first word line 71 and the second word line 72 are disposed on the first side and the second side of the channel region 22, respectively. Among them, the first word line 71 is adjacent to the first side of the channel region 22 and is opposite to at least a portion of the channel region 22, while the second word line 72 is adjacent to the second side of the channel region 22 and is opposite to at least a portion of the channel region 22. The first side of the channel region 22 and the second side of the channel region 22 are opposite along the extension direction of the bit line 30, so that the channel region 22 can be controlled by two word lines.

It can be understood that in the first word lines 71 and the second word line 72, regions facing the channel region 22 and aligned along the extension direction of the bit line 30 form a gate structure. A structure of the first word line 71 and a structure of the second word line 72 may be the same or different. The first word line 71 and the second word line 72 may be of a single-layer or multiple-layer structure, for example, including a second conductor layer. The second conductor layer is made of a material including a semiconductor material (such as, doped polycrystalline silicon, doped amorphous silicon, or the like), or a low-resistance metal material (such as, tungsten, aluminum, copper, or the like), which is not limited in the embodiments of the present application.

In order to achieve the control functions of the first word line 71 and the second word line 72, the semiconductor memory device further includes gate oxide layers 73, which are disposed at least between the first word line 71 and the channel region 22, as well as between the second word line 72 and the channel region 22. For example, the gate oxide layers 73 extend along the vertical direction. That is, a gate oxide layer 73 is provided between the first word line 71 and the insulating layer 50, and a gate oxide layer 73 is provided between the second word line 72 and the insulating layer 50. The gate oxide layer 73 is made of a material including silicon oxide, hafnium oxide, or the like.

The semiconductor memory device in the embodiments of the present application includes a substrate 10, a plurality of stacked structures, a bit line 30, a capacitor structure 40, an insulating layer 50, and a support layer 60. The plurality of stacked structures are isolated from one another in a vertical direction and disposed on the substrate 10. The stacked structure includes a semiconductor layer 20, and the semiconductor layer 20 includes a first doped region 21, a channel region 22, and a second doped region 23. The bit line 30 extends along a horizontal direction and is connected to the first doped region 21. The capacitor structure includes a bottom electrode 41 and a top electrode 42 arranged in a stacked configuration. The bottom electrode 41 is connected to the second doped region 23. The insulating layer 50 is disposed between adjacent capacitor structures 40, and the support layer 60 is disposed between insulating layers 50 and in direct contact with sidewalls, upper surfaces, and lower surfaces of the insulating layers 50. In this way, an end of the insulating layer 50 extends into the support layer 60, and the support layer 60 provides support for the insulating layer 50, thus maintaining the stability of the insulating layer 50 and avoiding bending of the insulating layer 50. Consequently, it avoids the bridging of capacitor structures 40 formed on the insulating layers 50 subsequently due to their bending, thereby ensuring the performance of the semiconductor memory device.

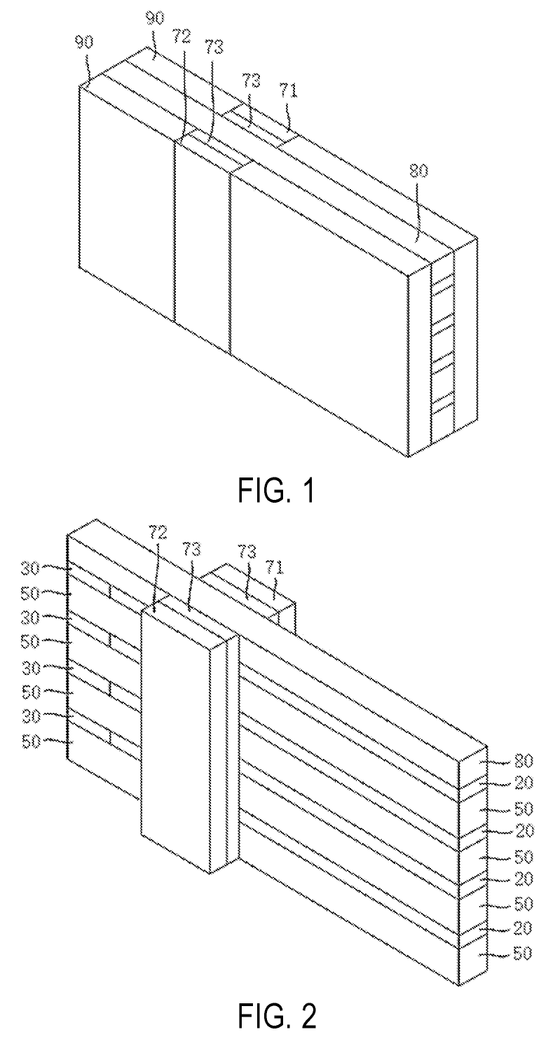

An embodiment of the present application further provides a manufacturing method of a semiconductor memory device. As shown in FIG. 1 to FIG. 11. The manufacturing method specifically includes: providing a substrate 10, and forming a plurality of stacked structures, a bit line 30, a capacitor structure 40, and a support layer 60. The plurality of stacked structures are isolated from one another in a vertical direction and disposed on the substrate. The stacked structure includes a semiconductor layer 20, and the semiconductor layer 20 includes a first doped region 21, a channel region 22, and a second doped region 23. The bit line 30 extends along a horizontal direction and is connected to the first doped region 21. The capacitor structure 40 includes a bottom electrode 41 and a top electrode 42 arranged in a stacked configuration. The bottom electrode 41 is connected to the second doped region 23, and the support layer 60 is in contact with a sidewall of the capacitor structure 40.

Among them, the substrate 10 is used to provide support. The substrate 10 is, for example, a silicon substrate, a silicon-containing (such as, silicon germanium) substrate, or a silicon on insulator (such as, SOI) substrate. The plurality of stacked structures, the bit line 30, the capacitor structure 40, and the support layer 60 are formed on the substrate 10. The plurality of stacked structures are arranged at intervals on the substrate 10 to achieve mutual isolation among the stacked structures. An arrangement direction of the plurality of stacked structures is D3 as shown in FIG. 6 and FIG. 10. The isolation layer 90 is formed (filled) at least between adjacent stacked structures, which is applied to achieve mutual isolation among the stacked structures.

Exemplarily, the isolation layer 90 is disposed on the substrate 10 and extends along the vertical direction. The isolation layer 90 is applied to ensure that there is no mutual conductivity between the stacked structures in the vertical direction. Among them, a top surface of the isolation layer 90 may be either higher than or flush with top surfaces of the stacked structures. A top surface refers to a surface away from the substrate 10. The vertical direction refers to a direction perpendicular to the top surface of the substrate 10, that is, D2 as shown in FIG. 6 and FIG. 10. The isolation layer 90 is made of a material including an insulating material, such as, silicon oxide, silicon nitride, carbon nitride silicon, or the like.

Each stacked structure includes at least one semiconductor layer 20. These semiconductor layers 20 are arranged at intervals in the vertical direction. The semiconductor layer(s) 20 in each stacked structure may be in contact with the substrate 10 or spaced apart from the substrate 10. The semiconductor layer 20 is made of a material including a semiconductor material, such as, monocrystalline silicon, polycrystalline silicon, amorphous silicon, or the like.

Each semiconductor layer 20 includes a first doped region 21, a channel region 22, and a second doped region 23 that are sequentially arranged. That is, two sides of the channel region 22 are respectively connected to the first doped region 21 and the second doped region 23. Among them, the first doped region 21, the channel region 22, and the second doped region 23 are adjacent in sequence and parallel to the top surface of the substrate 10. The arrangement direction of the first doped region 21, the channel region 22, and the second doped region 23 is a direction D1 as shown in FIG. 6 and FIG. 10, which may also be considered as an extension direction of the semiconductor layer 20.

A surface of the first doped region 21 and a surface of the channel region 22 that face each other may be overlapping, e.g., completely coincide. A surface of the second doped region 23 and a surface of the channel region 22 that face each other may be overlapping, e.g., completely coincide. Both the first doped region 21 and the second doped region 23 may be heavily doped regions, with doping achieved, for example, through ion implantation. The first doped region 21 may be used as a drain, which is connected to the bit line 30, and the second doped region 23 may be used as a source, which is connected to the capacitor structure 40.

Continuing to refer to FIG. 2, the manufacturing method further includes forming a word line extending along the vertical direction and being adjacent to the channel region 22. Specifically, the word line extends along a direction away from a top surface of the substrate 10. The word line is adjacent to the channel region 22 and is also used to form a gate, thereby controlling the channel region 22 to switch on or off. The word line may correspond to channel regions 22 of a plurality of semiconductor layers 20 in the same stacked structure, to simultaneously control the switching on or off of the plurality of channel regions 22.

In some embodiments, the word line includes a first word line 71 and a second word line 72. The first word line 71 is adjacent to a first side of the channel region 22, and the second word line 72 is adjacent to a second side of the channel region 22. The second side of the channel region 22 is opposite to the first side of the channel region 22 along an extension direction of the bit line 30. As shown in FIG. 10, the first word line 71 and the second word line 72 are disposed on the first side and the second side of the channel region 22, respectively. Among them, the first word line 71 is adjacent to the first side of the channel region 22 and is opposite to at least a portion of the channel region 22, while the second word line 72 is adjacent to the second side of the channel region 22 and is opposite to at least a portion of the channel region 22. The first side of the channel region 22 and the second side of the channel region 22 are opposite along the extension direction of the bit line 30, so that the channel region 22 can be controlled by two word lines.

It can be understood that in the first word lines 71 and the second word line 72, regions facing the channel region 22 and aligned along the extension direction of the bit line 30 form a gate structure. A structure of the first word line 71 and a structure of the second word line 72 may be the same or different. The first word line 71 and the second word line 72 may be of a single-layer or multiple-layer structure, for example, including a second conductor layer. The second conductor layer is made of a material including a semiconductor material (such as, doped polycrystalline silicon, doped amorphous silicon, or the like), or a low-resistance metal material (such as, tungsten, aluminum, copper, or the like), which is not limited in the embodiments of the present application.

In order to achieve the control functions of the first word line 71 and the second word line 72, the semiconductor memory device further includes gate oxide layers 73, which are disposed at least between the first word line 71 and the channel region 22, as well as between the second word line 72 and the channel region 22. For example, the gate oxide layers 73 extend along the vertical direction. That is, a gate oxide layer 73 is provided between the first word line 71 and the insulating layer 50, and a gate oxide layer 73 is provided between the second word line 72 and the insulating layer 50. The gate oxide layer 73 is made of a material including silicon oxide, hafnium oxide, or the like.

The bit line 30 is disposed on the substrate 10 and extends along a horizontal direction. The horizontal direction is parallel to the top surface of substrate 10. The bit line 30 is electrically connected to the first doped region 21. That is, there exists electrical conductivity between the bit line 30 and the first doped region 21. In some embodiments, a height of the bit line 30 matches that of the semiconductor layer 20. A top surface of the bit line 30 is higher than a bottom surface of the semiconductor layer 20 to which the bit line 30 is connected and is lower than or flush with a top surface of its connected semiconductor layer 20. Alternatively, a bottom surface of the bit line 30 is higher than or flush with a bottom surface of its connected semiconductor layer 20, and is lower than a top surface of its connected semiconductor layer 20. Specifically, a top surface of the bit line 30 is flush with a top surface of its connected semiconductor layer 20, and a bottom surface of the bit line 30 is flush with a bottom surface of its connected semiconductor layer 20, so that the bit line 30 and the semiconductor layer 20 are disposed on the same layer, thus facilitating the fabrication of the bit line 30 and improving the transmission performance between the bit line 30 and the corresponding semiconductor layer 20.

In some possible examples, an extension direction of the bit line 30 is parallel to the arrangement direction of the plurality of stacked structures, so that the bit line 30 may connect to a plurality of semiconductor layers 20, and the plurality of semiconductor layers 20 are located in different stacked structures, to simplify the structure of the semiconductor memory device and facilitate the improvement of storage density. Among them, the extension direction of bit line 30 is a direction D3 as shown in FIG. 6 and FIG. 10. The bit line 30 may have a single-layer structure or a multiple-layer structure. Exemplarily, the bit line 30 includes a first conductor layer. The first conductor layer is made of a material including a metal material, such as, a low-resistance metal material (including tungsten, aluminum, copper, or the like). The specific structure of the bit line 30 in the embodiments of the present application is not limited. There may be multiple bit lines 30, which are arranged at intervals in the vertical direction to avoid connections between adjacent bit lines 30. The number of the bit lines 30 may be consistent with the number of semiconductor layers 20 in the stacked structure, enabling each semiconductor layer 20 within each stacked structure to be individually lead out through the corresponding bit line 30.

Continuing to refer to FIG. 1 to FIG. 11, the capacitor structure 40 may store data. It includes a bottom electrode 41 and a top electrode 42 arranged in a stacked configuration, and the bottom electrode 41 and the top electrode 42 are spaced apart from each other. The bottom electrode 41 is further connected to the second doped region 23. For example, the bottom electrode 41 is disposed on a surface of the second doped region 23 away from the channel region 22. That is, the first doped region 21, the channel region 22, the second doped region 23, and the bottom electrode 41 are sequentially arranged. Surfaces of the bottom electrode 41 and the second doped region 23 that face each other are in close contact, e.g., completely coincide. The bottom electrode 41 and the top electrode 42 are made of a material including a low-resistance metal material (such as, titanium nitride, aluminum, titanium, copper, tungsten, or the like), or a semiconductor material (such as, silicon germanium, or the like), or a combination of the above materials. In order to achieve the storage function of the capacitor structure 40, a dielectric layer 43 is further formed between the top electrode 42 and the bottom electrode 41. The dielectric layer 43 is made of a material including, for example, silicon oxide, zirconium oxide, aluminum oxide, or the like.

The support layer 60 is disposed on a side of the semiconductor layer 20 away from the bit line 30. That is, the support layer 60 and the bit line 30 are respectively disposed on two sides of the semiconductor layer 20, and the above capacitor structure 40 may also be formed between the support layer 60 and the semiconductor layer 20. The support layer 60 may extend along the vertical direction and be in contact with a sidewall of the capacitor structure 40. For example, the support layer 60 may be in direct contact with a surface of the bottom electrode 41 away from the second doped region 23 to provide support for the capacitor structure 40, thereby avoiding bending of the capacitor structure 40, and enhancing the performance of the semiconductor memory device formed. The support layer 60 is made of a material including an insulating material with high hardness, such as, silicon nitride, silicon carbide nitride, or the like. Stacked structures may be formed on both sides of the support layer 60. That is, the stacked structures may also be arranged along the direction D1 as shown in FIG. 8 and FIG. 11. The support layer 60 may provide support for the stacked structures on both sides to improve the storage density of the semiconductor memory device.

In some embodiments, referring to FIG. 1 to FIG. 8, the support layer 60 is disposed around the bottom electrode 41, and is in direct contact with a sidewall, an upper surface, and a lower surface of the bottom electrode 41. Among them, the upper surface and the lower surface of the bottom electrode 41 are oppositely disposed in the vertical direction. An end of the bottom electrode 41 away from the second doped region 23 is located within the support layer 60. The support layer 60 is used to provide support for the capacitor structure 40, thus can avoid bending of the bottom electrode 41 and bridging between bottom electrodes 41, thereby ensuring the performance of the semiconductor memory device.

For example, the bottom electrode 41 includes a first side wall 44 and a second side wall 45 that are oppositely disposed, the first side wall 44 being in direct contact with the support layer 60, and the second side wall 45 being in direct contact with the second doped region 23. The bottom electrode 41 is made of a material, for example, the same as that of the semiconductor layer 20, so that the bottom electrode 41 and the semiconductor layer 20 form an integrated structure, thus facilitating the simultaneous production of the bottom electrode 41 and the semiconductor layer 20. The bottom electrode 41 and the semiconductor layer 20 are disposed on the same layer, and the bottom electrode 41 may be a portion of the semiconductor layer 20. The top electrode 42 is disposed between adjacent bottom electrodes 41, and the top electrode 42 is staggered with the semiconductor layers 20 in the vertical direction.

In this implementation, the manufacturing method of a semiconductor memory device further includes forming an insulating layer 50. The insulating layer 50 is disposed between adjacent semiconductor layers 20 to achieve mutual isolation between adjacent semiconductor layers 20 in the same stacked structure. The insulating layer 50 is formed (filled) at least between adjacent semiconductor layers 20, and is in complete contact with surfaces of two adjacent semiconductor layers 20 that face each other, thus ensuring effective isolation among the semiconductor layers 20. The insulating layer 50 is made of a material including, for example, silicon oxide, silicon nitride, phosphosilicate glass, or the like. The top electrode 42 is specifically formed on a surface of the insulating layer 50 facing the support layer 60. The top electrode 42 surrounds an outer circumference surface of the bottom electrode 41. That is, the top electrode 42 is sleeved on the bottom electrode 41 and spaced apart from the bottom electrode 41. The top electrode 42 may have an integrated structure. That is, a plurality of bottom electrodes 41 share one top electrode 42. The top electrode 42 is formed, for example, through a deposition process to facilitate the production of the top electrode 42.

In this embodiment, the dielectric layer 43 is disposed between the bottom electrode 41 and the top electrode 42, as well as between the support layer 60 and the top electrode 42. The dielectric layer 43 covers a portion of a surface of the bottom electrode 41. For example, the dielectric layer 43 covers a portion of an outer circumference surface of one end of the bottom electrode 41 adjacent to the second doped region 23. An end of the bottom electrode 41 away from the second doped region 23 extends into the support layer 60, and the dielectric layer 43 is not formed on this end. Specifically, the bottom electrode 41 and the dielectric layer 43 will be in contact with the support layer 60, and the dielectric layer 43 covers a portion of the surface of the bottom electrode 41 that faces the top electrode 42. The top electrode 42 is spaced apart from the support layer 60.

As a possible implementation, a specific process of the manufacturing method in the embodiments of the present application is as follows.

Referring to FIG. 1 and FIG. 2, an initial stacked structure is formed, which includes alternately disposed initial insulating layers and initial semiconductor layers, and a mask layer 80 is formed on the initial stacked structure. Among them, the initial insulating layer and the initial semiconductor layer will be subsequently formed into an insulating layer 50 and a semiconductor layer 20, respectively. The initial insulating layer, the initial semiconductor layer, and the mask layer 80 may all be formed using a deposition process, which are complete film layers.

A patterning process is performed on the mask layer 80, and the patterned mask layer 80 is used as a mask to etch the initial stacked structure, to form stacked structures, as well as isolation trenches to isolate respective stacked structures. By means of photolithography and etching, a desired pattern is formed in the mask layer 80 and then transferred downwards. The formed stacked structure includes insulating layers 50 and semiconductor layers 20 alternately disposed in sequence. The mask layer 80 may be consumed during the etching process of the initial stacked structure, or it may be removed after the formation of the stacked structures, or removed after the formation of the capacitor structures. After the formation of the stacked structures, an isolation layer 90 may also be formed inside the isolation trench to make each stacked structure independent from each other.

As shown in FIG. 1 and FIG. 2, bit lines 30 are formed on one side of the semiconductor layers 20, and the bit lines 30 are connected to the semiconductor layers 20. Among them, the bit line 30 may be formed either by removing a portion of the semiconductor layer 20 and subsequently depositing a bit line material, or by removing a portion of another film layer adjacent to the semiconductor layer 20 and subsequently depositing a bit line material.

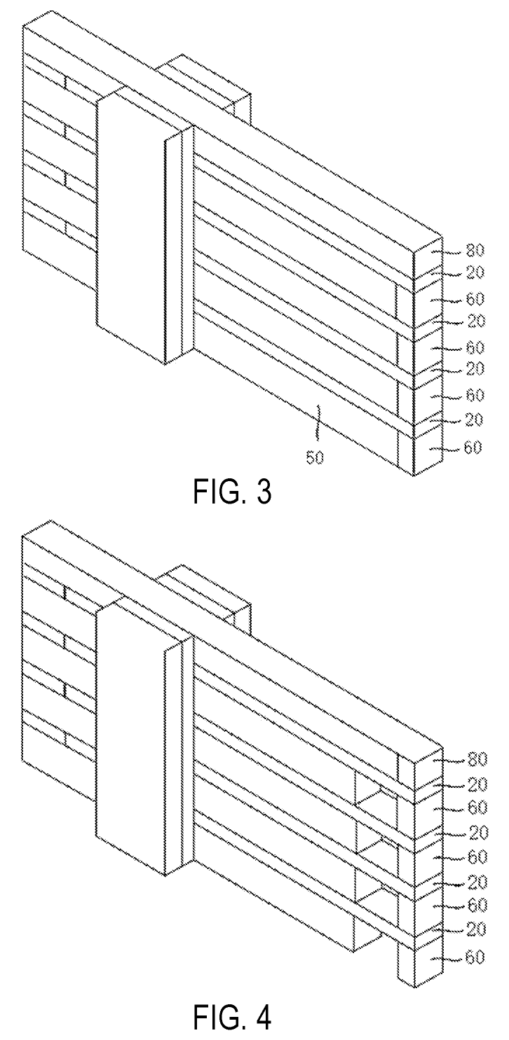

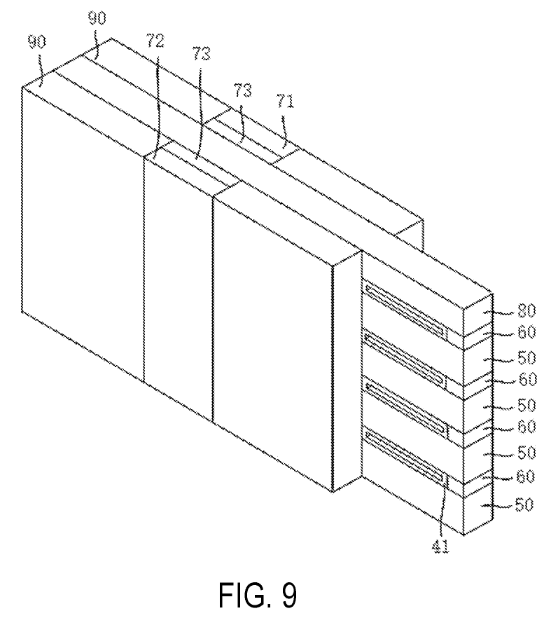

Referring to FIG. 3 and FIG. 9, a portion of the insulating layer 50 away from an end of the bit line 30 is removed, and a support layer 60 is formed. Before the removal of the portion of the insulating layer 50, a portion of the isolation layer 90 away from the bit line 30 may also be removed. This can increase an exposed area of the insulating layer 50 and facilitate the removal of the portion of the insulating layer 50. The support layer 60 may be formed through deposition. A support layer 60 is filled between adjacent semiconductor layers 20. A support layer 60 is also formed on a side of the semiconductor layer 20 away from the bit line 30. Before or after the formation of the support layer 60, a gate oxide layer 73 is formed on both sides of the stacked structure, correspondingly, a first word line 71 and a second word line 72 are formed on sides of the gate oxide layer 73 away from the stacked structure. Exemplarily, after the formation of the support layer 60, a portion of the isolation layer 90 is removed to expose at least a portion of the semiconductor layer 20. Subsequently, a gate oxide material and a word line material are sequentially deposited at the exposed positions to form the gate oxide layers 73, the first word line 71, and the second word line 72.

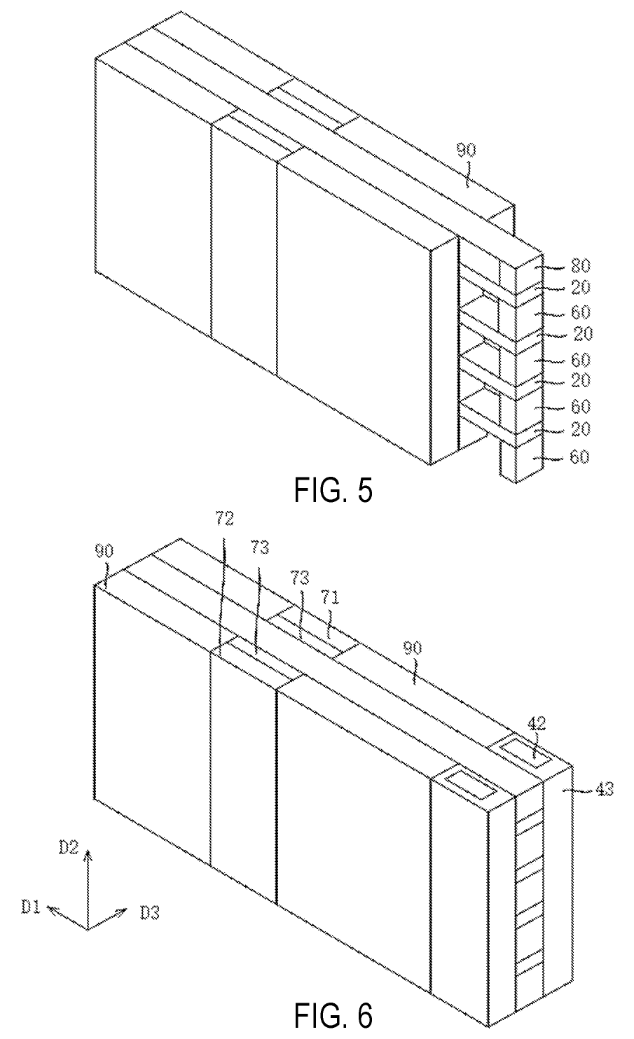

Referring to FIG. 4 to FIG. 7, a portion of the insulating layer 50 adjacent to the support layer 60 is removed, then a dielectric layer 43 and a top electrode 42 are deposited in sequence. The dielectric layer 43 and the top electrode 42 fills up a gap between adjacent semiconductor layers 20. That is, a portion of the semiconductor layer 20 is used as the bottom electrode 41. Among them, as shown in FIG. 4 and FIG. 5, before the removal of the portion of the insulating layer 50, a portion of the isolation layer 90 away from the support layer 60 may also be removed. This can increase an exposed area of the insulating layer 50 and facilitate the removal of the portion of the insulating layer 50. As shown in FIG. 6 and FIG. 7, the dielectric layer 43 is deposited on the exposed surface of the semiconductor layer 20, and the dielectric layer 43 does not fill up the gap between adjacent semiconductor layers 20 in the vertical direction. Then the top electrode 42 is deposited on a surface of the dielectric layer 43, and the top electrode 42 fills up the remaining gap between adjacent semiconductor layers 20 in the vertical direction.

In another possible implementation, referring to FIG. 9 to FIG. 11, the manufacturing method further includes forming an insulating layer 50. The insulating layer 50 is disposed between adjacent capacitor structures 40. The support layer 60 is disposed between insulating layers 50 and is in direct contact with sidewalls, upper surfaces, and lower surfaces of the insulating layers 50. The insulating layer 50 is specifically formed between adjacent bottom electrodes 41. The insulating layer 50 is made of a material including, for example, silicon oxide, silicon nitride, phosphosilicate glass, or the like. The insulating layer 50 includes a first end and a second end that are oppositely disposed. The first end of the insulating layer 50 may protrude from an end of the bit line 30 away from the first doped region 21 or be flush with the end of the bit line 30 away from the first doped region 21, and the second end of the insulating layer 50 protrudes from an end of the bottom electrode 41 away from the second doped region 23. The first end and the second end of the insulating layer 50 are oppositely disposed along an arrangement direction of the semiconductor layer 20 and the capacitor structure 40.

The support layer 60 covers one end of the insulating layer 50. The support layer 60 provides support for the insulating layer 50. This helps maintain the stability of the insulating layer 50 and avoid bending of the insulating layer 50. Consequently, it avoids the bridging of capacitor structures 40 formed on the insulating layers 50 subsequently due to their bending, thereby ensuring the performance of the semiconductor memory device. Among them, the upper surface and the lower surface of the insulating layer 50 are spaced apart in the vertical direction, and the sidewall of the insulating layer 50 is a surface on a side of the insulating layer 50 that is away from the bit line 30. Specifically, the bottom electrode 41 is in contact with the support layer 60. The dielectric layer covers an entire surface of the bottom electrode 41 that faces the top electrode 42, and the dielectric layer 43 and the top electrode 42 are both spaced apart from the support layer 60.

In this implementation, the insulating layer 50 is also disposed between adjacent semiconductor layers 20. In this way, the insulating layer 50 is applied to further achieve isolation between adjacent semiconductor layers 20 in the vertical direction. Furthermore, the insulating layer 50 also extends between adjacent bit lines 30 to achieve isolation between adjacent bit lines 30 in the vertical direction. As shown in FIG. 11, the bottom electrode 41 covers a portion of a surface of the insulating layer 50, the semiconductor layer 20 covers a portion of a surface of the insulating layer 50, and the bit line 30 covers a portion of a surface of the insulating layer 50.

As a possible implementation, referring to FIG. 1 to FIG. 3, as well as FIG. 9 to FIG. 11, a specific process of the manufacturing method in the embodiments of the present application is as follows.

An initial stacked structure is formed, which includes alternately disposed initial insulating layers and initial semiconductor layers, and a mask layer 80 is formed on the initial stacked structure. Among them, the initial insulating layer and the initial semiconductor layer will be subsequently formed into an insulating layer 50 and a semiconductor layer 20, respectively. The initial insulating layer, the initial semiconductor layer, and the mask layer 80 may all be formed using a deposition process, which are complete film layers.

A patterning process is performed on the mask layer 80, and the patterned mask layer 80 is used as a mask to etch the initial stacked structure, to form stacked structures, as well as isolation trenches to isolate respective stacked structures. By means of photolithography and etching, a desired pattern is formed in the mask layer 80 and then transferred downwards. The formed stacked structure includes insulating layers 50 and semiconductor layers 20 alternately disposed in sequence. The mask layer 80 may be consumed during the etching process of the initial stacked structure, or it may be removed after the formation of the stacked structures, or removed after the formation of the capacitor structures. After the formation of the stacked structures, an isolation layer 90 may also be formed inside the isolation trench to make each stacked structure independent from each other.

Bit lines 30 are formed on one side of the semiconductor layers 20, and the bit lines 30 are connected to first doped regions 21 of the semiconductor layers 20. Among them, the bit line 30 may be either formed by removing a portion of the semiconductor layer 20 and subsequently depositing a bit line material, or by removing a portion of another film layer adjacent to the semiconductor layer 20 and subsequently depositing a bit line material.

A portion of the semiconductor layer 20 away from an end of the bit line 30 is removed, and a support layer 60 is formed. Before the removal of the portion of the insulating layer 50, a portion of the isolation layer 90 away from the bit line 30 may also be removed. This can increase an exposed area of the insulating layer 50 and facilitate the removal of the portion of the insulating layer 50. A support layer 60 may be formed through deposition. A support layer 60 is filled between adjacent semiconductor layers 20. A support layer 60 is also formed on a side of the semiconductor layer 20 away from the bit line 30. Before or after the formation of the support layer 60, gate oxide layers 73 are formed on both sides of the stacked structure, correspondingly, a first word line 71 and a second word line 72 are formed on sides of the gate oxide layers 73 away from the stacked structure. Exemplarily, after the formation of the support layer 60, a portion of the isolation layer 90 is removed to expose at least a portion of the semiconductor layer 20. Subsequently, a gate oxide material and a word line material are sequentially deposited at the exposed positions to form the gate oxide layers 73, the first word line 71, and the second word line 72.

A portion of the semiconductor layer 20 adjacent to the support layer 60 is removed, then a bottom electrode 41, a dielectric layer 43, and a top electrode 42 are deposited in sequence to form a capacitor structure 40. The bottom electrode 41, the dielectric layer 43, and the top electrode 42 fill up a gap between adjacent insulating layers 50. As shown in FIG. 9, before the removal of the portion of the semiconductor layer 20, a portion of the isolation layer 90 away from the support layer 60 may also be removed. This can increase an exposed area of the semiconductor layer 20 and facilitate the removal of the portion of the semiconductor layer 20, so as to expose a portion of the insulating layer 50. The bottom electrode 41 is deposited on the exposed surface of the insulating layer 50, and the bottom electrode 41 does not fill up the gap between adjacent insulating layers 50 in the vertical direction. Then the dielectric layer 43 is deposited, and the dielectric layer 43 does not fill up the gap between adjacent insulating layers 50 in the vertical direction. Then the top electrode 42 is deposited on a surface of the dielectric layer 43, and the top electrode 42 fills up the remaining gap between adjacent insulating layers 50 in the vertical direction.

In the above two implementations and other embodiments, both an orthographic projection of the top electrode 42 and an orthographic projection of the bottom electrode 41 onto the support layer 60 are located within the contour of a corresponding surface of the support layer 60. As shown in FIG. 7 and FIG. 8, the orthographic projection of the bottom electrode 41 onto the support layer 60 is located within the contour of the corresponding surface of the support layer 60, and the orthographic projection of the top electrode 42 onto the support layer 60 is also located within the contour of the corresponding surface of the support layer 60. Therefore, in both the vertical direction and the horizontal direction, the support layer 60 has a larger area, so that the support layer 60 can fully support all bottom electrodes 41 and make complete contact with the first side walls 44 of the bottom electrodes 41. This configuration can enhance the support effect. At the same time, it can also increase the contact area between the support layer 60 and the dielectric layer 43, further improving the support provided by the support layer 60.

A manufacturing method of a semiconductor memory device provided in an embodiment of the present application includes: providing a substrate 10, and forming a plurality of stacked structures, a bit line 30, a capacitor structure 40, and a support layer 60. The plurality of stacked structures are isolated from one another in a vertical direction and disposed on the substrate. The stacked structure includes a semiconductor layer 20, and the semiconductor layer 20 includes a first doped region 21, a channel region 22, and a second doped region 23. The bit line 30 extends along a horizontal direction and is connected to the first doped region 21. The capacitor structure 40 includes a bottom electrode 41 and a top electrode 42 arranged in a stacked configuration. The bottom electrode 41 is connected to the second doped region 23. The support layer 60 is in contact with a sidewall of the capacitor structure 40. The support layer 60 can provide support for the capacitor structure 40 during its formation process, thereby avoiding bending of the capacitor structure 40 and enhancing the performance of the semiconductor memory device formed.

Finally, it should be noted that persons of ordinary skill in the art will easily come up with other embodiments of the present invention after considering the specification and practicing the invention disclosed herein. The present invention is intended to encompass any variations, uses or adaptive changes of the present invention, which follow the general principles of the present invention and include common knowledge or conventional technical means in the technical field not disclosed in the present invention, and are not limited to the precise structures described above and shown in the drawings, and may be modified and changed in various ways without departing from the scope thereof. The scope of the present invention is limited only by the appended claims.

### Reference Signs List

Description of the reference signs:

10- substrate;

20- semiconductor layer; 21- first doped region; 22- channel region; 23- second doped region;

30- bit line;

40- capacitor structure; 41- bottom electrode; 42- top electrode; 43- dielectric layer; 44- first side wall; 45- second side wall;

50- insulating layer;

60- support layer;

71- first word line; 72- second word line; 73- gate oxide layer;

80- mask layer;

90- isolation layer.

What is claimed is:

1. A semiconductor memory device, comprising:
a substrate;
a plurality of stacked structures isolated from one another in a vertical direction and disposed on the substrate, wherein the stacked structure comprises a semiconductor layer, and the semiconductor layer comprises a first doped region, a channel region, and a second doped region;
a bit line extending along a horizontal direction and being connected to the first doped region;
a capacitor structure comprising bottom electrodes and a top electrode, wherein the bottom electrodes are connected to the second doped region; and
a support layer disposed between adjacent bottom electrodes and being in direct contact with sidewalls, upper surfaces, and lower surfaces of the bottom electrodes.

2. The semiconductor memory device according to claim 1, wherein the bottom electrode comprises a first sidewall and a second sidewall that are oppositely disposed, the first sidewall is in direct contact with the support layer, and the second sidewall is in direct contact with the second doped region.

3. The semiconductor memory device according to claim 2, wherein an orthographic projection of the top electrode and an orthographic projection of the bottom electrode are both located within a contour of a corresponding surface of the support layer.

4. The semiconductor memory device according to claim 1, further comprising: a word line extending along the vertical direction and being adjacent to the channel region.

5. The semiconductor memory device according to claim 2, further comprising: a word line extending along the vertical direction and being adjacent to the channel region.

6. The semiconductor memory device according to claim 3, further comprising: a word line extending along the vertical direction and being adjacent to the channel region.

7. The semiconductor memory device according to claim 1, further comprising an insulating layer and a dielectric layer;
wherein the insulating layer is disposed between adjacent semiconductor layers;
wherein the dielectric layer is disposed between the bottom electrode and the top electrode, as well as between the support layer and the top electrode, and the dielectric layer covers a portion of a surface of the bottom electrode.

8. The semiconductor memory device according to claim 2, further comprising an insulating layer and a dielectric layer;
wherein the insulating layer is disposed between adjacent semiconductor layers;
wherein the dielectric layer is disposed between the bottom electrode and the top electrode, as well as between the support layer and the top electrode, and the dielectric layer covers a portion of a surface of the bottom electrode.

9. A semiconductor memory device, comprising:
a substrate;
a plurality of stacked structures isolated from one another in a vertical direction and disposed on the substrate, wherein the stacked structure comprises a semiconductor layer, and the semiconductor layer comprises a first doped region, a channel region, and a second doped region;
a bit line extending along a horizontal direction and being connected to the first doped region;
a capacitor structure comprising a bottom electrode and a top electrode arranged in a stacked configuration, wherein the bottom electrode is connected to the second doped region;
an insulating layer disposed between adjacent capacitor structures;
a support layer disposed between insulating layers and being in direct contact with sidewalls, upper surfaces, and lower surfaces of the insulating layers.

10. The semiconductor memory device according to claim 9, wherein the bottom electrode comprises a first sidewall and a second sidewall that are oppositely disposed, the first sidewall is in direct contact with the support layer, and the second sidewall is in direct contact with the second doped region.

11. The semiconductor memory device according to claim 10, wherein an orthographic projection of the top electrode and an orthographic projection of the bottom electrode are both located within a contour of a corresponding surface of the support layer.

12. The semiconductor memory device according to claim 9, further comprising: a word line extending along the vertical direction and being adjacent to the channel region.

13. The semiconductor memory device according to claim 9, wherein the bit line and the support layer are respectively disposed on opposite sides of the semiconductor layer.

14. The semiconductor memory device according to claim 9, wherein the insulating layer is further disposed between adjacent semiconductor layers;
wherein the semiconductor memory device further comprises a dielectric layer, wherein the dielectric layer is disposed between the bottom electrode and the top electrode, and the bottom electrode covers a portion of a surface of the insulating layer.

15. A manufacturing method of a semiconductor memory device, comprising:
providing a substrate; and
forming a plurality of stacked structures, a bit line, a capacitor structure, and a support layer;
wherein the plurality of stacked structures are isolated from one another in a vertical direction and disposed on the substrate, the stacked structure comprises a semiconductor layer, and the semiconductor layer comprises a first doped region, a channel region, and a second doped region;
the bit line extends along a horizontal direction and is connected to the first doped region;
the capacitor structure comprises a bottom electrode and a top electrode, wherein the bottom electrode is connected to the second doped region; and
the support layer is in contact with a sidewall of the capacitor structure.

16. The manufacturing method according to claim 15, wherein the support layer is disposed between adjacent bottom electrodes and in direct contact with sidewalls, upper surfaces, and lower surfaces of the bottom electrodes.

17. The manufacturing method according to claim 15, further comprising: forming an insulating layer, wherein the insulating layer is disposed between adjacent capacitor structures, and the support layer is disposed between insulating layers and in direct contact with sidewalls, upper surfaces, and lower surfaces of the insulating layers.

18. The manufacturing method according to claim 17, further comprising: forming a dielectric layer, wherein the dielectric layer is disposed between the bottom electrode and the top electrode, and the bottom electrode covers a portion of a surface of the insulating layer.

19. The manufacturing method according to claim 18, wherein the insulating layer is further disposed between adjacent semiconductor layers.

20. The manufacturing method according to claim 19, wherein the dielectric layer is disposed between the bottom electrode and the top electrode, as well as between the support layer and the top electrode, and the dielectric layer covers a portion of a surface of the bottom electrode.
